(19) United States
(12) Patent Application Publication
(10) Pub. No.: US 2014/0304562 A1
(43) Pub. Date: Oct. 9, 2014

(54) Method for Testing Paths to Pull-Up and Pull-Down of Input/Output Pads

(71) Applicant: LSI CORPORATION, San Jose, CA (US)

(72) Inventors: Ramesh C. Tekumalla, Breinigsville, PA (US); Vijay Sharma, Pune (IN)

(73) Assignee: LSI CORPORATION, San Jose, CA (US)

(21) Appl. No.: 13/872,424

(22) Filed: Apr. 29, 2013

Related U.S. Application Data
(60) Provisional application No. 61/809,579, filed on Apr. 8, 2013.

(51) Int. Cl. G01R 31/3185

(52) U.S. Cl. CPC G01R 31/318544
USPC 714/726

(57) ABSTRACT

A SCAN chain architecture for each path in a circuit having combinational paths includes a control mechanism to control one or more flip flops and multiplexers to direct operational or test signals. Operational signals are sent along at least one combinational path to a pull-up/pull-down for at least one input/output pad and an operational voltage is recorded. Test signals are sent along at least one alternative path to an alternative input/output and a test voltage is recorded. The operational voltage is compared to the test voltage to identify a combinational path fault.

### PRIORITY

The present application claims the benefit under 35 U.S.C. §119(e) of U.S. Provisional Application Ser. No. 61/809,579, filed Apr. 8, 2013, which is incorporated herein by reference.

### FIELD OF THE INVENTION

The present invention is directed generally toward testing paths in circuits.

### BACKGROUND OF THE INVENTION

The paths to the Pull-up/Pull-down of input/output pads are generally combinational paths. Combinational paths like these are not covered by conventional SCAN testing and are difficult to test explicitly. Faults in these paths can lead to excessive current draw during latch up testing, and it is difficult to diagnose whether the fault is due to the Pull-up or Pull-down path of the input/output pad.

Consequently, it would be advantageous if an apparatus existed that is suitable for testing paths to the pull-up/pull-down of input/output pads.

### SUMMARY OF THE INVENTION

Accordingly, the present invention is directed to a novel method and apparatus for testing paths to the pull-up/pull-down of input/output pads.

One embodiment of the present invention is a SCAN chain architecture for each path in a circuit having combinational paths. The architecture includes a control mechanism to exercise each SCAN chain.

Another embodiment of the present invention is a method for testing paths in a combinational circuit. The method includes receiving a first voltage through a combinational data path and receiving a second voltage through an alternate data path. The first voltage and second voltage are compared to identify any faults in the combinational path.

It is to be understood that both the foregoing general description and the following detailed description are exemplary and explanatory only and are not restrictive of the invention claimed. The accompanying drawings, which are incorporated in and constitute a part of the specification, illustrate an embodiment of the invention and together with the general description, serve to explain the principles.

### BRIEF DESCRIPTION OF THE DRAWINGS

The numerous advantages of the present invention may be better understood by those skilled in the art by reference to the accompanying figures in which:

FIG. 1 shows a block diagram of a system for testing pull-up/pull-down paths;

FIG. 2 shows a block diagram of a system for testing pull-up/pull-down paths according to at least one embodiment of the present invention;

FIG. 3 shows a block diagram of a circuit for testing pull-up/pull-down paths according to at least one embodiment of the present invention;

FIG. 4 shows a block diagram of a circuit for testing pull-up/pull-down paths with SCAN channels according to at least one embodiment of the present invention;

FIG. 5 shows a flowchart of a method for testing pull-up/pull-down paths in a combinational circuit;

FIG. 6 a block diagram of a computer apparatus for implementing embodiments of the present invention

### DETAILED DESCRIPTION OF THE INVENTION

Reference will now be made in detail to the subject matter disclosed, which is illustrated in the accompanying drawings. The scope of the invention is limited only by the claims; numerous alternatives, modifications and equivalents are encompassed. For the purpose of clarity, technical material that is known in the technical fields related to the embodiments has not been described in detail to avoid unnecessarily obscuring the description.

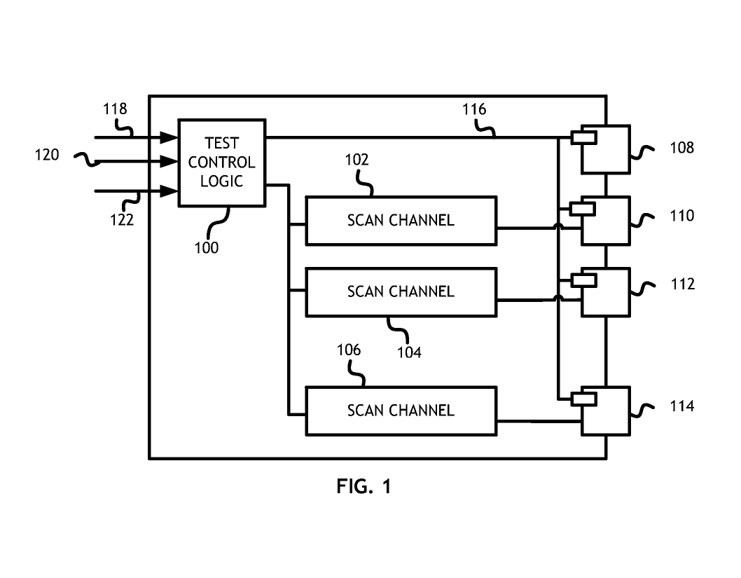

Referring to FIG. 1, a block diagram of a system for testing pull-up/pull-down paths is shown. The system includes test control logic 100 that receives input signals through one or more primary inputs 118, 120, 122. The primary inputs 118, 120, 122 are pins that receive signals such as a signal to put the system in a testing mode. The test control logic 100 is connected to one or more SCAN channels 102, 104, 106, each SCAN channel 102, 104, 106 is connected to an input/output pad 110, 112, 114. SCAN channels 102, 104, 106 perform SCAN chain testing of flip-flops in an integrated circuit.

During normal operations, the test control logic 100 controls pull-up and pull-down signals for each of the input/output pads 110, 112, 114 through a combinational path 116. The combinational path 116 is not included in any SCAN channel 118, 120, 122 or other SCAN architecture; therefore, faults in the combinational path 116 cannot be tested for structural defects that may cause undesirable current draw. For example, during latch-up testing, defects in the combinational path 116 could cause excess current leakage or other faulty behavior.

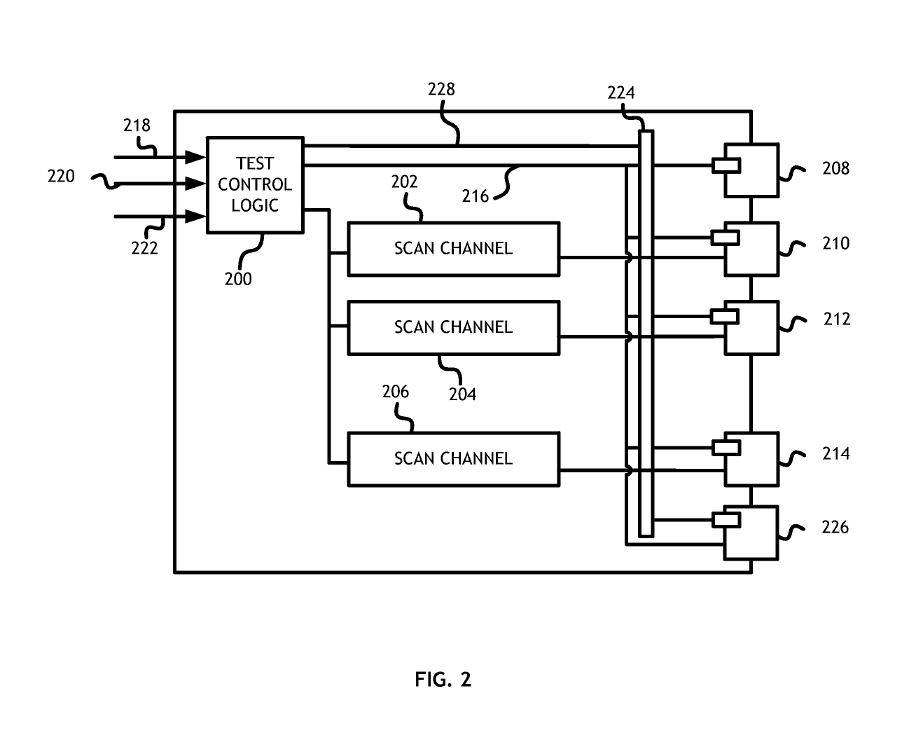

Referring to FIG. 2, a block diagram of a system for testing pull-up/pull-down paths according to at least one embodiment of the present invention is shown. In at least one embodiment of the present invention, the system includes test control logic 200 that receives input signals through one or more primary inputs 218, 220, 222. The primary inputs 218, 220, 222 are pins that receive signals such as a signal to put the system in a testing mode. The test control logic 200 is connected to one or more SCAN channels 202, 204, 206, each SCAN channel 202, 204, 206 is connected to an input/output pad 210, 212, 214. SCAN channels 202, 204, 206 perform SCAN chain testing of flip-flops in an integrated circuit.

In at least one embodiment, the test control logic 200 controls pull-up and pull-down signals for each of the input/output pads 210, 212, 214, 226 through a combinational path 216. The test control logic 200 is also connected to a path testing element 224, which is a set of serial flip-flops that control the pull-up/pull-down inputs of the input/output pads. The test control logic 200 controls the path testing element 224 through signals sent through one or more combinatorial paths 216, 228. The path testing element 224 is connected to each input/output pads 208, 210, 212, 214, 226.

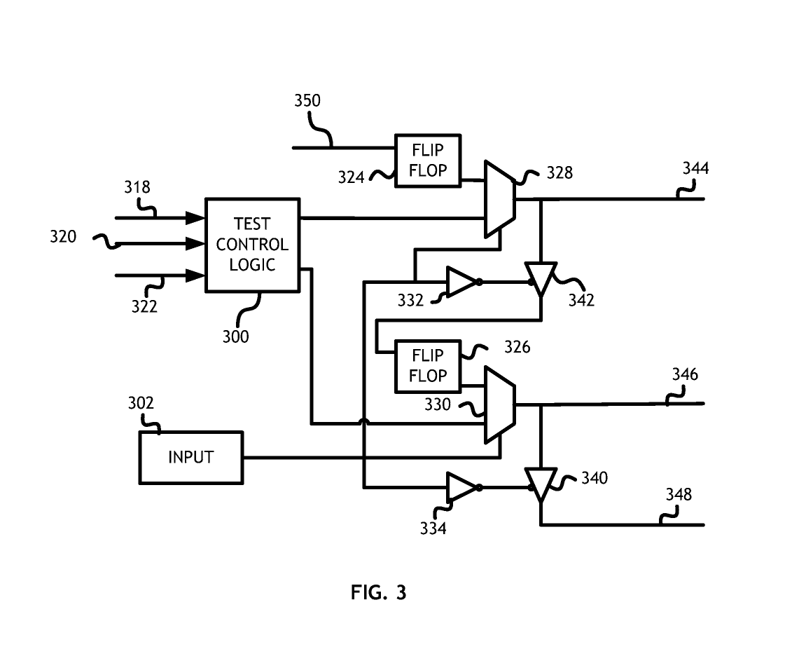

Referring to FIG. 3, a block diagram of a circuit for testing pull-up/pull-down paths according to at least one embodiment of the present invention is shown. In at least one embodiment, a path test control element includes a plurality of elements for testing a combinational path 344, 346. Test control logic 300 receives input signals from one or more primary inputs 318, 320, 322 and produces either an operational signal or a test mode signal based on those input signals. The test control logic 300 sends signals to a first multiplexer 328 and a second multiplexer 330. The first multiplexer 328 also receives a signal from a first flip flop 324. The first flip flop 324 receives a flip flop input signal 350. The flip flop input signal 350 may originate from the test control logic 300 or from a separate test mode input pin. The first multiplexer 328 selects either the first flip flop 324 generated signal or the test control logic 300 generated signal based on bits from a test mode input 302 such as a test data register. The output from the first multiplexer 328 serves as input to a first three-state gate 342. In one embodiment, the first three-state gate 342 is controlled by the output from a first inverter 332. The first inverter 332 receives an input from the test mode input 302 and outputs an inverted signal to the first three-state gate 342. In another embodiment, the first three-state gate 342 is controlled directly by the test mode input 302.

In at least one embodiment, the second multiplexer 330 receives signals from the test control logic 300 and a second flip flop 326. The second flip flop 326 is controlled by the output from the first three-state gate 342. The second multiplexer 330 selects either the second flip flop 326 generated signal or the test control logic 300 generated signal based on the bits from the test mode input 302. The output from the second multiplexer 330 serves as input to a second three-state gate 340. In one embodiment, the second three-state gate 340 is controlled by the output from a second inverter 334. The second inverter 334 receives an input from the test mode input 302 and outputs an inverted signal to the second three-state gate 340. In another embodiment, the second three-stage gate 340 is controlled directly by the test mode input 302.

In at least one embodiment, where dictated by a signal from the test mode input 302, the first three-state gate 342 and second three-state gate 340 are in a normal operating state such that the output of the first three-state gate 342 and second three-state gate 340 can be driven high or low based on the respective inputs.

In one exemplary embodiment, where a test mode input 302 indicates normal operation (for example, with a bit value of zero), a signal will pass-through the first multiplexer 328 to a combinational path 344 and a signal will pass-through the second multiplexer 330 to combinational path 346, while the first three-state gate 342 and second three-state gate 340 are in a high impedance state and will not allow a signal to pass through. The test mode input 302 also dictates which signal passes through the first multiplexer 328 and the second multiplexer 330. A signal from the test control logic 300 passes through the first multiplexer 328 along a combinational path 344 to a pull-up/pull-down of an input/output pad. Likewise, a signal from the test control logic 300 passes through the second multiplexer 330 along a combinational path 346 to one or more pull-up/pull-downs of one or more input/output pads.

Alternatively, where a test mode input 302 indicates SCAN operation (for example, with a bit value of one), the first three-state gate 342 and second three-state gate 340 will allow a signal to pass-through. The test mode input 302 also dictates which signal passes through the first multiplexer 328 and the second multiplexer 330. A signal from the first flip-flop 324 passes through the first multiplexer 328 and the first three-state gate 342, and serves as the input to the second flip-flop 326. The output from the second flip-flop 326 passes through the second multiplexer 330 and the second three-state gate 340 to a test path 348 connected to an input/output pad. In at least one embodiment, each output from the test control logic 300 is associated with one flip-flop 324, 326 and one multiplexer 328, 330. An output voltage at the test path 348 can be compared to a voltage along a combinational path 344, 346 to determine a fault in a combinational path 344, 346.

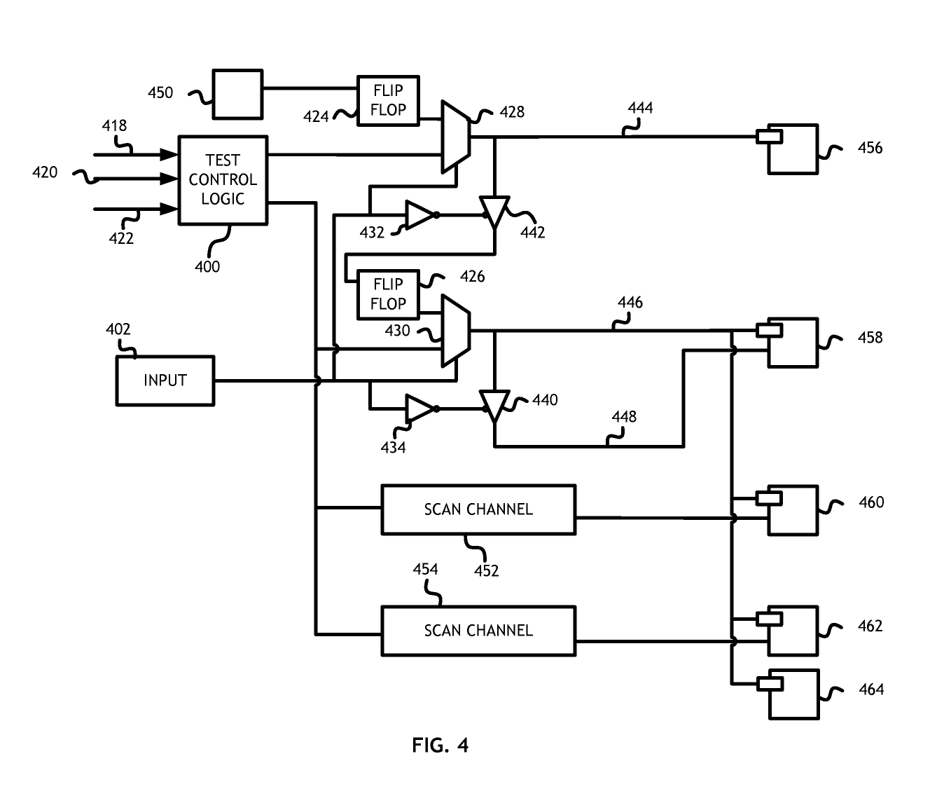

Referring to FIG. 4, a block diagram of a circuit for testing pull-up/pull-down paths with SCAN channels according to at least one embodiment of the present invention is shown. In at least one embodiment of the present invention, where a circuit such as the one shown in FIG. 3 is implemented in a system SCAN chain testing, the circuit receives one or more primary inputs 418, 420, 422 to a test control logic 400. The circuit may also receive an input to a SCAN mode pin 450.

In one exemplary embodiment, where a test mode input 402 indicates normal operation (for example, with a bit value of zero), a signal will pass-through the first multiplexer 428 to a combinational path 444 and a signal will pass-through the second multiplexer 430 to combinational path 446, while a first three-state gate 442 and a second three-state gate 440, controlled by a first inverter 432 and second inverter 434 respectively, are in a high impedance state and will not allow a signal to pass through. The test mode input 402 also dictates which signal passes through a first multiplexer 428 and a second multiplexer 430. A signal from the test control logic 400 passes through the first multiplexer 428 along a combinational path 444 to a pull-up/pull-down of a first input/output pad 456. Likewise, a signal from the test control logic 400 passes through the second multiplexer 430 along a combinational path 446 to one or more pull-up/pull-downs of one or more input/output pads 458, 460, 462, 464.

Alternatively, where a test mode input 402 indicates SCAN operation (for example, with a bit value of one), the first three-state gate 442 and second three-state gate 440 will allow a signal to pass-through. The test mode input 402 also dictates which signal passes through the first multiplexer 428 and the second multiplexer 430. A signal from a first flip-flop 424, controlled by a SCAN mode pin 450, passes through the first multiplexer 428 and the first three-state gate 442, and serves as the input to the second flip-flop 426. The output from the second flip-flop 426 passes through the second multiplexer 430 and the second three-state gate 440 to a test path 448 connected to second input/output pad 458. The output at the second input/output pad 458 is used to determine the integrity of the combinational paths 444, 446 during normal operation by comparing the voltage at the first input/output pad 456 to the voltage at the second input/output pad 458 during SCAN operation.

Furthermore, during SCAN operation, output from the test control logic 400 passes through one or more SCAN channels 452, 454 to one or more input/output pads 460, 462. The output at the one or more input/output pads 460, 462 is used for SCAN chain testing.

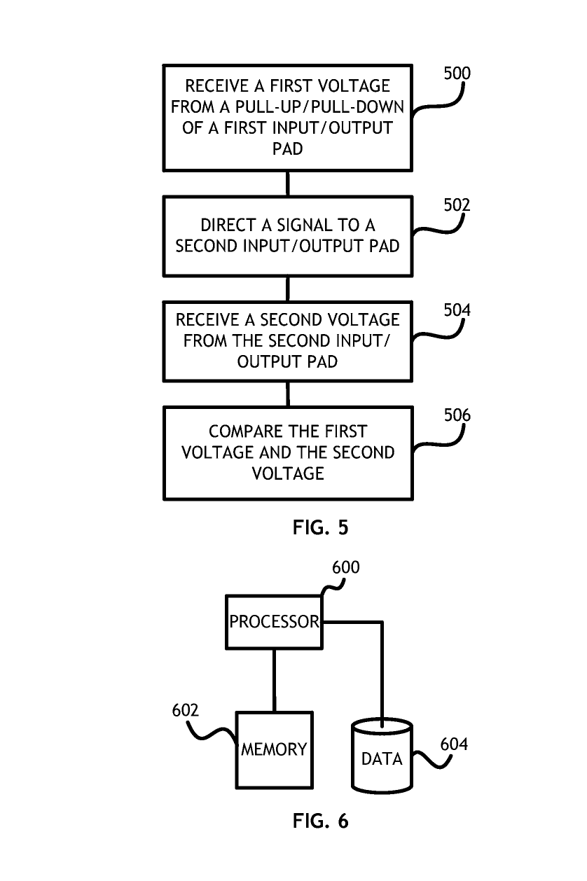

Referring to FIG. 5, a flowchart of a method for testing pull-up/pull-down paths in a combinational circuit is shown. In at least one embodiment of the present invention, the method includes receiving 500 a first voltage from a first input/output pad through a pull-up/pull-down. The first voltage is based on a signal from a test control logic element. One or more signals from the test control logic element and a test mode input direct 502 signals away from the first input/output pad and associated combinational path, and toward a second input/output pad. A second voltage is then received 504 from the second input/output pad. The second voltage may be based on a signal from the test control logic element or a signal received form a SCAN mode pin. The first voltage and the second voltage are then compared 506 to determine if the combinational path includes any faults.

Referring to FIG. 6, a block diagram of a computer apparatus for implementing embodiments of the present invention is shown. The computer apparatus includes a processor 600 and memory 602 connected to the processor 600. In at least one embodiment, a data storage element 604 is also connected to the processor 600. In at least one embodiment of the present invention, the processor 600 produces a first voltage, and in some embodiments receives the first voltage from a first input/output pad through a pull-up/pull-down. The first voltage is based on a signal from a test control logic element. The processor 600 then directs signals away from the first input/output pad and associated combinational path, and toward a second input/output pad. The processor 600 then produces or receives a second voltage from the second input/output pad. The second voltage may be based on a signal from the test control logic element or a signal received form a SCAN mode pin. The processor 600 then compares the first voltage and the second voltage to determine if the combinational path includes any faults.

It is believed that the present invention and many of its attendant advantages will be understood by the foregoing description of embodiments of the present invention, and it will be apparent that various changes may be made in the form, construction, and arrangement of the components thereof without departing from the scope and spirit of the invention or without sacrificing all of its material advantages. The form herein before described being merely an explanatory embodiment thereof, it is the intention of the following claims to encompass and include such changes.

What is claimed is:

1. A circuit, comprising:
a test control logic having at least one input and at least one output;
a first flip flop;
a first multiplexer; and
a first three-state gate,
wherein:
an output from the first flip flop is configured as an input to the first multiplexer;
a first output of the at least one outputs of the test control logic is configured as an input to the first multiplexer; and
the output of the first multiplexer is a combinational path to a pull-up/pull-down of an input/output pad.

2. The circuit of claim 1, wherein the first flip flop comprises a SCAN mode input configured to receive a signal to determine the state of the first flip flop.

3. The circuit of claim 1, further comprising a test mode input configured to send a signal to determine an output of the first multiplexer and a state of the first three-state gate.

4. The circuit of claim 3, wherein the test mode input is configured to send a signal causing the first multiplexer to pass-through a signal from the test control logic to a pull-up/pull-down of an input/output pad connected to a combinatorial path, and causing the first three-state gate to enter a high impedance state.

5. The circuit of claim 3, wherein the test mode input is configured to send a signal causing the first multiplexer to pass-through a signal from the first flip flop, and causing the first three-state gate to pass-through a signal from the first multiplexer to an input/output pad.

6. The circuit of claim 1, further comprising:
a second flip flop;
a second multiplexer;
a second-three-state gate connected to an output of the second multiplexer; and
a test mode input connected to the first multiplexer, the second multiplexer, the first three-state gate, and the second three-state gate,
wherein:
an output from the second flip flop is configured as an input to the second multiplexer;
a second output of the at least one outputs of the test control logic is configured as an input to the second multiplexer; and
the output of the second three-state gate is a combinational path to one or more pull-up/pull-downs of one or more input/output pads.

7. The circuit of claim 6, wherein the second flip flop is configured to receive a signal from the first three-state gate to determine the state of the second flip flop.

8. The circuit of claim 6, wherein the test mode input is configured to send a signal causing the first multiplexer to pass-through a signal from the test control logic to a pull-up/pull-down of an input/output pad connected to a combinatorial path, causing and the second multiplexer to pass-through a signal from the test control logic to at least one pull-up/pull-down of at least one input/output pad, and causing the first three-state gate and the second three-state gate to enter a high impedance state.

9. The circuit of claim 6, wherein the test mode input is configured to send a signal causing:
the first multiplexer to pass-through a signal from the first flip flop;
the first three-state gate to pass-through a signal from the first multiplexer to determine the state of the second flip flop;
the second multiplexer to pass-through a signal from the second flip flop; and
the second three-state gate to pass-through a signal from the second multiplexer to an input/output pad.

10. The circuit of claim 6, wherein the test mode input comprises a test data register.

11. A computer apparatus, comprising:
a processor comprising:
a test control logic having at least one input and at least one output;
a first flip flop;
a first multiplexer; and
a first-three-state gate connected to an output of the first multiplexer;
a memory connected to the processor; and
computer executable program code configured to execute on the processor,
wherein:
an output from the first flip flop is configured as an input to the first multiplexer;
a first output of the at least one outputs of the test control logic is configured as an input to the first multiplexer; and
the output of the first three-state gate is a combinational path to a pull-up/pull-down of an input/output pad.

12. The computer apparatus of claim 11, further comprising a test mode input configured to send a signal to determine an output of the first multiplexer and a state of the first three-state gate.

13. The computer apparatus of claim 12, wherein the test mode input is configured to send a signal causing the first multiplexer to pass-through a signal from the first flip flop, and causing the first three-state gate to pass-through a signal from the first multiplexer to an input/output pad.

14. The computer apparatus of claim 11, wherein the processor further comprises:
a second flip flop;
a second multiplexer
a second-three-state gate connected to an output of the second multiplexer; and
a test mode input connected to the first multiplexer, the second multiplexer, the first three-state gate, and the second three-state gate,
wherein:
an output from the second flip flop is configured as an input to the second multiplexer;
a second output of the at least one outputs of the test control logic is configured as an input to the second multiplexer; and
the output of the second three-state gate is a combinational path to one or more pull-up/pull-downs of one or more input/output pads.

15. The computer apparatus of claim 14, wherein the test mode input is configured to send a signal causing:
the first multiplexer to pass-through a signal from the first flip flop;
the first three-state gate to pass-through a signal from the first multiplexer to determine the state of the second flip flop;
the second multiplexer to pass-through a signal from the second flip flop; and
the second three-state gate to pass-through a signal from the second multiplexer to an input/output pad.

16. The computer apparatus of claim 15, wherein the processor is configured to identify at least one fault in a combinational path by comparing a first voltage to a second voltage.

17. A method for testing combinational paths, comprising:
producing a first voltage;
directing the first voltage to a pull-up/pull-down associated with a first input/output pad, through a combinational path;
producing a second voltage;
directing the second voltage to a second input/output pad; and
comparing the first voltage to the second voltage.

18. The method of claim 17, further comprising identifying at least one fault in the combinational path.

19. The method of claim 17, wherein directing the second voltage to the second input/output pad comprises selecting a signal with a SCAN test mode input.

20. The method of claim 19, wherein the second voltage is a signal received from a flip flop.
